(19) United States
(12) Patent Application Publication
(10) Pub. No.: US 2025/0062529 A1
(43) Pub. Date: Feb. 20, 2025

(54) PHASE SHIFTER

(71) Applicant: Visban, Co., Ltd., Tokyo (JP)

(72) Inventors: Arokia Nathan, Hertfordshire (GB); Suk-Bae Cha, Tokyo (JP); Ryosuke Kuwada, Kanagawaken (JP)

(21) Appl. No.: 18/720,570

(22) PCT Filed: Dec. 16, 2022
(86) PCT No.: PCT/GB2022/053282

§ 371 Date: Jun. 14, 2024

(30) Foreign Application Priority Data
Dec. 20, 2021 (GB) 2118518.6

(51) Int. Cl. H01Q 3/36; H01Q 21/06; H03H 7/18; H04B 7/024; H04B 7/06

(52) U.S. Cl. CPC H01Q 3/36; H01Q 21/064; H03H 7/18; H04B 7/024; H04B 7/0617

(57) ABSTRACT

A phase shifter includes an active matrix transistor array. Each transistor of the active matrix transistor array is configured to control a voltage bias across a corresponding voltage-controlled capacitor of voltage-controlled capacitors to control a capacitance of the corresponding voltage-controlled capacitor. The phase shifter further includes signal channels. Each signal channel of the signal channels has a first end and a second end and is AC coupled at a point between the first end and the second end to one or more of the voltage-controlled capacitors. The phase shifter is configured to control a phase shift applied to each corresponding signal channel of the signal channels by setting the voltage bias across each of the one or more of the voltage-controlled capacitors coupled to the corresponding signal channel.

### RELATED APPLICATIONS

This application claims the benefit under 35 U.S.C. § 371 of International Patent Application No. PCT/GB2022/053282, filed Dec. 16, 2022, which claims priority to United Kingdom Application No. GB 2118518.6, filed Dec. 20, 2021, the contents of each are incorporated by reference in their entirety.

### TECHNICAL FIELD

The present disclosure relates to a phase shifter which may be scaled to a large number of channels. The present disclosure also relates to applications of the phase shifter to beamforming, in particular radio, audio and ultrasonic applications.

### BACKGROUND

Beamforming as a technique is known for a variety of different types of waves, including audio, ultrasonic and radio. The scaling of phased arrays is limited by the capacity to control the phase shifts applied to signals received from and/or transmitted by individual transducers.

Beamforming may be relevant in wireless communications networks. As wireless communications networks move towards higher frequencies to improve data rates, the corresponding decrease in wavelengths can lead to issues with providing uniform coverage in areas without line of sight to a transmitter, for example, in urban areas, forested areas, inside structures and so forth.

As wireless communications networks start to move to frequencies at and above 5 GHz (sometimes termed “fifth generation” or “5G”), the effects of attenuation by atmospheric gasses such as oxygen (O₂), carbon dioxide (CO₂) and water vapor (H₂O) can be significant in some frequency bands. Atmospheric weather effects can exacerbate such issues, for example attenuation may reach in the region of 60 dB·m⁻¹.

Providing wireless network coverage to the interior of structures such as buildings and sports stadiums is already an issue for frequencies below 5 GHz. Moving to higher frequencies will cause further degradation of signal intensities penetrating into structures.

Improvements in building glass relating to thermal regulation, for example inclusion of thin metallized layers to help keep buildings cooler, may further attenuate radio signals from the exterior.

Signal relaying systems have been proposed, see for example CN 106992807 A, US 2018/139521 A1 and US 2015/380816 A1.

Deploying a network of line-of-sight relaying transceivers, for example for deploying a 5G mobile network, will require significant numbers of steerable phased array antennae. Cost and complexity of each transceiver are important factors. Whilst it is possible to produce arrays including large numbers of individually addressable antennae, there is also the question of how to drive each with a signal having an independently variable phase for beamforming.

Varactor diodes have been applied to antenna arrays used for beamforming, see for example JP 2009-038453 A, JP 2006-101439 A and JP 2004-080626 A.

### SUMMARY

According to a first aspect of the present disclosure there is provided a phase shifter including an active matrix transistor array, each transistor configured to control a voltage across a corresponding voltage-controlled capacitor to control a capacitance of that voltage-controlled capacitor. The phase shifter also includes a number of signal channels. Each signal channel has first and second ends and is AC coupled at a point between the first and second ends to one or more of the voltage-controlled capacitors. The phase shifter is configured to control the phase shift applied to each signal channel by setting the voltage across each of the one or more voltage-controlled capacitors coupled to that signal channel.

A storage capacitor may be connected in parallel with each voltage-controlled capacitor.

Each signal channel may take the form of a transmission line. A transmission line may take the form of a micro-strip transmission line.

A voltage-controlled capacitor is any device having a capacitance which may be varied as a function of a voltage input and/or applied bias across the voltage-controlled capacitor. The voltage-controlled capacitor may exhibit voltage dependent capacitance based at least partly on geometric effects such as modulation of the width of a depletion layer of a semiconductor junction. Additionally or alternatively, the voltage-controlled capacitor may exhibit voltage dependent capacitance based at least partly on modulation of a dielectric constant of a material included in the capacitor. The voltage-controlled capacitor may include, or take the form of, a varactor diode (sometimes also called a “varicap”). If the voltage-controlled capacitor is a varactor diode, the bias applied should be a reverse bias. The voltage-controlled capacitor may include ferroelectric material.

Each signal channel may be coupled to a single voltage-controlled capacitor. Each signal channel may be coupled to two or more voltage-controlled capacitors.

The active matrix transistor array may include thin-film transistors. Each (i.e. every) transistor of the active matrix transistor array may take the form of a thin-film transistor. The active matrix transistor array may be configured such that the voltage across each voltage-controlled capacitor may be set independently by setting a drive line of the corresponding transistor to a desired voltage and opening the gate of that transistor using a signal line of that transistor.

The phase shifter may be configured to receive or generate a phase image. Each pixel of the phase image may correspond to a transistor of the active matrix transistor array, and may store a voltage for application to the associated voltage-controlled capacitor. The phase shifter may be configured to set the voltages of each voltage-controlled capacitor according to the phase image.

The phase image may alternatively be described as a hologram. Herein the term “hologram” may also be used to describe a 3D wave pattern formed by interference between signals phase shifted by different amounts by the phase shifter. In other words, the term “hologram” may be applied to the phase image, to the resulting phase shifted electrical signals after transmission through the phase shifter and/or a wave pattern emitted based on the phase shifted electrical signals.

Each signal channel may include one or more amplifiers between the respective first and second ends.

Each signal channel may include one or more filters between the respective first and second ends.

The active matrix transistor array and the voltage-controlled capacitors may be supported by a common substrate. The storage capacitors may also be supported by the common substrate. The common substrate may be a flexible film or sheet. Electrical components of the phase shifter may be supported, deposited, patterned and/or integrated on one or both sides of the common substrate. Electrical components of the phase shifter may include, without limitation, the active matrix transistor array, the voltage-controlled capacitors, and when included the storage capacitors. Interconnections between electrical components of the phase shifter supported on opposite faces of the common substrate may be provided using through vias.

The common substrate may include, or take the form of, a laminate. If the common substrate is a laminate, one or more electrical components of the phase shifter may be supported, deposited, patterned and/or integrated on and/or within one or more internal layers of the laminate. If the common substrate is a laminate, the laminate may include one or more layers of glass and/or plastic and/or adhesive. The laminate may include one or more conductor layers. Conductor layers of the laminate may be internal (i.e. between the first and second faces), and/or external (i.e. supported on the first and/or second faces). One or more layers of the laminate may support one or more components of the phase shifter. The common substrate may take the form of a multi-layer printed circuit board.

The active matrix transistor array may be integrated on and/or in the common substrate. The active matrix transistor array may be flip-chip bonded to the common substrate. The storage capacitors may be integrated on and/or in the common substrates. The storage capacitors may be flip-chip bonded to the common substrate. The voltage-controlled capacitors may be integrated on and/or in the common substrates. The voltage-controlled capacitors may be flip-chip bonded to the common substrate. Electrical components of the phase shifter may be flip-chip bonded to one or both sides of the common substrate.

The common substrate may be transparent. Transparent may correspond to the common substrate having a minimum transmission of 50% for visible wavelengths. Visible wavelength may correspond to a range between 380 nm and 750 nm.

A transparent common substrate may include, or be formed from, glass. The transparent common substrate may include, or take the form of, one or more plastics including but not limited to polycarbonate (PC), polyimide (PI), polyethylene terephthalate (PET), polyethylene naphthalate (PEN), cyclo-olefin polymer (COP), or any other polymer having sufficient mechanical strength to support the circuit and sufficient transparency to be seen through.

Signal channels may take the form of microstrip transmission lines supported by the common substrate (or on an internal layer when a laminate). The phase shifter may include a first microstrip line supported on a first face of the common substrate and a second microstrip line support on a second, opposite face of the common substrate. The first and second microstrip lines may be connected by corresponding vias. Vias connecting between microstrip lines supported on the first and second faces may be impedance matched to the microstrip lines. The phase shifter may include a number of first microstrip lines supported on the first face. The phase shifter may include a number of second microstrip lines supported on the second face. Any microstrip line may be connected by vias extending through the common substrate to one or more microstrip lines and/or other components of the circuit supported on the opposite side of the common substrate. Compared to, for example, radiative transfer or capacitive coupling between the first and second faces, such physical connections do not require that the common substrate is formed from a material or materials having low dielectric loss properties. Though not required, materials having low dielectric loss properties may still be used.

When one or more electrical components of the phase shifter are flip-chip bonded to the common substrate, such components may be flip-chip bonded to the common substrate in accordance with the Heterogeneous Integration Roadmap, HIR. The Heterogeneous Integration Roadmap (HIR) is a set of guidelines developed for silicon systems-in-package (SiP) technologies. HIR may refer to, for example, the guidelines set out in the publication of the HIR 2019 edition.

If the phase shifter includes filters, the filters may additionally be supported by, or integrated with, the common substrate. The phase shifter may include one or more filters in the form of film bulk acoustic resonators, FBARs. A filter may include, or take the form of, a thin-film bulk acoustic resonator, TFBAR. A filter may include, or be formed from, metamaterials. Metamaterial filters suitable for use in the phase shifter include, without being limited to, metamaterial filters described in “Metamaterial Structure Inspired Miniature RF/Microwave Filters”, Abdullah Alburaikan, PhD Thesis (2016), The University of Manchester, https://www.escholar.manchester.ac.uk/uk-ac-man-scw:305308, (see in particular pages 56 onwards). One or more filters may be directed formed on, or integrated with, the common substrate. Additionally or alternatively, one or more filters may be flip-chip bonded to the common substrate.

Filters may be integrated into some or all of the signal channels, for example, when a signal channel is provided by a transmission line, a filter may be integrated in the form of one or more distributed-element filters. In other words, filters may be provided in the form of a variation in impedance along a portion of a transmission line.

One of more signal channels may be switchable between two or more filters, each having a distinct bandwidth. Each signal channel may be switchable between two or more filters, each having a distinct bandwidth. A signal channel may be switchable between two or more filters using transistors supported on the common substrate along with the active matrix transistor array, or user transistors integrally formed with the active matrix transistor array.

The common substrate may incorporate a heat spreader layer (not shown). The heat spreader layer may be incorporated during a heterogeneous integration fabrication process. A heat spreader layer may enable operation at higher power and/or using a higher density electrical components and interconnects without requiring a fan or other cooling method. For example, a ground plane layer for the phase shifter may be formed from copper and may additionally serve as a heat spreader layer.

If the phase shifter includes amplifiers, the amplifiers may additionally be supported by, or integrated with, the common substrate. The phase shifter may include one or more amplifiers in the form of CMOS amplifiers supported by the common substrate.

The active matrix transistor array and the voltage-controlled capacitors may be integrated as a single component. The single component including the active matrix transistor array and the voltage-controlled capacitors may be supported by the common substrate. The active matrix transistor array and the voltage-controlled capacitors may be formed on a single glass substrate.

The active matrix transistor array and the voltage-controlled capacitors may be formed on a single semiconductor die. The semiconductor die may be packaged and mounted to the common substrate in any manner described hereinbefore in relation to electrical components of the phase shifter. The storage capacitors may additionally be integrated with the single component. At least a portion of each signal channel may be integrated with the single component.

The phase shifter may be configured to apply phase shifts to audio frequency signals. Audio frequencies signals may correspond to a range between and including 20 Hz and 20 kHz.

The phase shifter may be configured to apply phase shifts to ultrasound frequency signals. Ultrasound frequencies may correspond to a range between and including 20 kHz and 18 MHz. Ultrasound frequencies may correspond to a range used for non-destructive testing. Ultrasound frequencies may correspond to a range used for range/distance finding. Ultrasound frequencies may correspond to a range used for medical scanning. Ultrasound frequencies may correspond to a range used for manipulating and/or modifying materials, for example breakdown of kidney stones.

The phase shifter may be configured to apply phase shifts to radio frequency signals.

The phase shifter may be configured for radio frequency signals having carrier frequencies between and including 5 GHz and 1 THz. The phase shifter may be configured for radio frequency signals having carrier frequencies between and including 5 GHz and 300 GHz. The phase shifter may be configured for radio frequency signals having carrier frequencies between and including 30 GHz and 300 GHz. The phase shifter may be configured for radio frequency signals having carrier frequencies within one or more of the K (20 GHz to 40 GHz), L (40 GHz to 60 GHz) and M (60 GHz to 100 GHz) bands defined by NATO. The phase shifter may be configured for radio frequency signals having carrier frequencies within one or more of the Ka (27 GHz to 40 GHz), V (40 GHz to 75 GHz) and W (75 GHz to 110 GHz) bands defined by the Institute of Electrical and Electronics Engineers (IEEE). The phase shifter may be configured for radio frequency signals having carrier frequencies exceeding 300 GHz. The phase shifter may be configured for radio frequency signals having carrier frequencies equaling or exceeding 1 THz. The phase shifter may be configured for radio frequency signals which are 5G signals. The phase shifter may be configured for radio frequency signals which are 6G signals. The phase shifter may be configured for radio frequency signals which are 7G signals.

A radio may include a first phase shifter in the form of the phase shifter described hereinbefore. The radio may also include a number of first antennae. Each first antenna may be connected to a radio frequency transceiver circuit via a respective signal channel of the first phase shifter. The radio frequency transceiver circuit may be configured to control the plurality of first antennae as a first phased array by performing beamforming of radio signals received by and/or transmitted from the plurality of first antennae using the first phase shifter.

The radio frequency transceiver circuit may be configured as a radio receiver. The radio frequency transceiver circuit may be configured as a radio transmitter. The radio frequency transceiver circuit may be configured as a radio transmitter and receiver (i.e. the radio overall is a transceiver). The radio may be configured as a base station of a wireless communication network.

The number of first antenna may be less than or equal to the number of signal channels of the first phase shifter.

Each first antenna may be connected to the respective signal channel of the first phase shifter via one or more amplifiers.

Some or all of the amplifiers may take the form of low noise amplifiers. Some or all of the amplifiers may take the form of power amplifiers. When the radio frequency transceiver circuit is configured as a transmitter and receiver, each first antenna may be connected to the respective signal channel of the first phase shifter via a path which is switchable between a low noise amplifier in a receive mode and a power amplifier in a transmit mode. When the radio frequency transceiver circuit is configured as a transmitter and receiver, a subset of the first antennae may be receive antennae connected to the respective signal channels of the first phase shifter via one or more low noise amplifiers, and the remaining first antennae (i.e. the complement of the subset) may be transmit antennae connected to the respective signal channels of the first phase shifter via one or more power amplifiers.

Each first antenna may be connected to the respective signal channel of the first phase shifter via one or more filters.

The plurality of first antennae may be disposed in an array. The geometry of the array of first antennae may correspond to the geometry of the active matrix transistor array. The geometry of the array of first antennae may differ from the geometry of the active matrix transistor array.

The first antennae may be integrated with the first phase shifter on the same substrate or within the same laminate. The first antennae may be integrated on the common substrate of the phase shifter.

One, some or all components of the radio frequency transceiver circuit may be integrated on the same substrate, or within the same laminate as the first phase shifter (and optionally the first antennae), for example the common substrate. One, some or all components of the radio frequency transceiver circuit may be flip-chip bonded to a substrate or laminate supporting or including the first phase shifter (and optionally the first antennae), for example the common substrate.

The first antennae may be supported on a transparent substrate. The transparent substrate may correspond to the common substrate of the phase shifter. The transparent substrate may be separate to the common substrate of the phase shifter.

The radio may be configured to relay or re-broadcast received radio signals.

The radio may also include a second phase shifter which is a phase shifter as described hereinbefore. The radio may also include a number of second antennae. Each second antenna may be connected to the radio frequency transceiver circuit via a respective signal channel of the second phase shifter. The radio frequency transceiver circuit may be configured to control, using the first phase shifter, the plurality of first antennae as a first phased array to receive radio signals, the first phased array being directional and controllably orientable to a receive direction. The radio frequency transceiver circuit may be configured to control, using the second phase shifter, the plurality of second antennae as a second phased array to retransmit the radio signals received using the first phased array, the second phased array being directional and controllably orientable to a transmit direction.

The first and second phase shifters may be provided by, or may take the form of, separate devices. The first and second phase shifters may be supported by and/or integrated with a shared substrate. The first and second phase shifters may be provided by, or may take the form of, a single phase shifter, with the first and second phase shifters corresponding to different regions of the active matrix transistor array.

A system may include a number of as described hereinbefore. Each radio of the two or more radios may be configured to coordinate beamforming with each other radio of the two or more radios.

The radios may be located in the same general vicinity, for example within a 200 m sphere. Each of the radios may be located within 200 m, within 100 m, within 50 m, within 20 m or within 10 m of at least one other radio belonging to the system.

The radios may be connected via a wired network. The radios may be connected via a wireless network. The radios may be connected via a network including wired and wireless links.

The system may also include a central control unit configured to coordinate beamforming of the plurality of radios. The central control unit may take the form of one radio of the radios belonging to the system. Each radio may include a processing unit and the system may be configured such that coordination of beamforming is executed in a distributed manner, using the processing units of two or more radios belonging to the system.

The radios belonging to the system may be configured to coordinate beamforming to direct reception and/or transmission of two or more radios towards a first external source. The radios belonging to the system may be configured to coordinate beamforming towards at least two spatially separated external sources.

The radios belonging to the system may be supported by a structure. The structure may be a building. Each radio may be supported by a window of the building. Each radio may be supported by a different window. Two or more radios may be supported by the same window. The structure may be a bus shelter, a lamp post, or any other item of street furniture. Supported by a structure may include attachment to the structure, mounting to the structure, and so forth. Supported by a structure may additionally or alternatively include radios being incorporated into, or integrally formed with, the structure. The radios belonging to the system may be supported by two or more separate structures (structures having the same meaning as already explained).

All or some of the radios belonging to the system may be arranged in an array, such that the first phased arrays of first antennae form a first macro-phased array. When second phased arrays of second antennae are included, these may additionally or alternatively be arranged to form a second macro-phase arrays.

An audio device may include the phase shifter when configured to apply phase shifts to audio frequency signals. The audio device may also include a number of audio transducers. Each audio transducer may be connected to an audio frequency transmitter and/or receiver circuit via respective signal channels of the phase shifter. The phase shifter may provide beamforming to control the plurality of audio transducers as a phased audio array.

The audio transducers may take the form of microphones and audio device may take the form of a directional microphone. The audio transducers may take the form of speakers and the audio device may take the form of a directional speaker. The audio transducers may include a number of microphones and a number of speakers and the audio device may take the form of a directional audio transceiver. The audio transducers may include one or more piezoelectric audio transducers.

The number of audio transducers may be less than or equal to the number of signal channels of the phase shifter.

The audio device may include features corresponding to any features or functions of the radio. A system including a number of audio devices may include features corresponding to any features or functions of the system including a number of radios. Definitions applicable to the radio or the system including a number of radios may be equally applicable to the audio device and/or a system including a number of audio devices.

An ultrasonic device may include the phase shifter when configured to apply phase shifts to ultrasound frequency signals. The ultrasonic device may also include a number of ultrasonic transducers. Each ultrasonic transducer may be connected to an ultrasonic frequency transmitter and/or receiver circuit via respective signal channels of the phase shifter. The phase shifter may provide beamforming to control the plurality of ultrasonic transducers as a phased ultrasonic array.

The ultrasonic device may take the form of a directional ultrasound receiver. The ultrasound device may take the form of a directional ultrasound transmitter. The ultrasound device may take the form of a directional audio transceiver. The ultrasonic transducers may include piezoelectric transducers.

The number of ultrasonic transducers may be less than or equal to the number of signal channels of the phase shifter.

The ultrasonic device may include features corresponding to any features or functions of the radio. A system including a number of ultrasonic devices may include features corresponding to any features or functions of the system including a number of radios. Definitions applicable to the radio or the system including a number of radios may be equally applicable to the ultrasonic device and/or a system including a number of ultrasonic devices.

According to a second aspect of the present disclosure there is provided a method of controlling a phase shifter according to the first aspect. The method includes addressing each transistor of the active matrix transistor array and setting the voltage across the connected voltage-controlled capacitor to cause a capacitance of that voltage-controlled capacitor to correspond to a given phase shift of a signal propagating via the coupled signal channel.

The method may include features corresponding to any features or functions of the phase shifter, the radio, the system including a number of radios devices, the audio device and/or the ultrasound device. Definitions applicable to the radio or the system including a number of radios may be equally applicable to the method.

### BRIEF DESCRIPTION OF THE DRAWINGS

Certain embodiments of the present disclosure will now be described, by way of example, with reference to the accompanying drawings in which:

FIG. 1 illustrates a phase shifter;

FIG. 2 is a circuit schematic for a portion of a phase shifter;

FIG. 3 is a circuit schematic for an example of coupling a signal channel to two or more voltage-controlled capacitances;

FIG. 4 illustrates integrating amplification and/or filtering into a signal channel of a phase shifter;

FIG. 5 illustrates a radio incorporating a phase shifter for beamforming;

FIG. 6 illustrates an exemplary array of antennae for a radio;

FIG. 7 is a circuit schematic for a portion of a phase shifter coupled between an antenna and a radio frequency transceiver circuit;

FIG. 8 illustrates a first integrated configuration of radio components;

FIG. 9 illustrates a second integrated configuration of radio components;

FIG. 10 illustrates an integral device structure;

FIG. 11 illustrates a first exemplary antenna array;

FIG. 12 illustrates a second exemplary antenna array;

FIG. 13 illustrates a third exemplary antenna array;

FIG. 14 illustrates a fourth exemplary antenna array;

FIG. 15 illustrates a system including a number of radios;

FIG. 16 illustrates an audio device incorporating a phase shifter for beamforming; and

FIG. 17 illustrates an ultrasonic device incorporating a phase shifter for beamforming.

### DETAILED DESCRIPTION

In the following description, like parts are denoted by like reference numerals.

Whilst the use of varactor diodes for applying phase shifts to signals is known, an outstanding question is how to control the individual phase shifts applied to signals as the number of channels scales to large numbers. The present specification describes phase shifters which enable scaling the number of elements in a phase array using active matrix addressing schemes. Using the approach of the present specification, numbers of voltage-controlled capacitors numbering thousands, tens of thousands, hundreds or thousands, or even more than a million may be controlled to apply phase shifts to corresponding signal channels. Additionally, varactor diodes, and even antennae, may be integrated with a TFT active matrix control scheme, providing compact radio phased arrays which may be manufactured through modification of existing production lines.

In the field of wireless communications networks specifically, the problems of line-of-sight to a base station and atmospheric and/or weather attenuation of radio signals may be addressed by adding further wireless transceivers to a wireless network. However, in order to do this in practice, wireless transceivers are required which are small, high-gain, steerable and inexpensive and which do not require large amounts of power. The direction of the Poynting vector of radio signals, especially for non-line-of-sight environments, is important to maximizing quality of service performance. It is also desirable that the wireless transceivers used should be aesthetically unobtrusive, i.e. small and preferably easy to disguise and/or integrate into an environment. The present specification describes, amongst other applications, phase shifters and antenna assemblies for radio transceivers which may help to address these issues.

The current infrastructure for wireless communications is expected to encounter limitations and underlying issues which will make it difficult to scale towards higher frequencies, for example towards (or beyond) mm-waves. As the demand for higher bandwidth is driven ever upwards for new services such as mobile data, content streaming and so forth, the size of an area (or “cell”) covered by a single transmitter tower had become increasingly small. This trend is expected to continue for frequencies above 5 GHz, often referred to as “5G”. The current conventional infrastructure of cell towers is already approaching its limits, and a new approach is required as wireless communications networks increasing move towards a line-of-sight, point-to-multipoint system operating at high frequencies and high data rates. Such high frequency communications, for example mm-wave, may also benefit considerably from the use of massively multi-input-multiple-output antenna architectures to allow beam-forming and beam-steering. Highly directional operation may help to avoid issues with multi-path interference.

Driven by consumer demands for increasingly diverse and immersive mobile data services, for example High-definition video streaming, cloud-based services, augmented reality and so forth, next generation wireless communication networks and systems will need to offer high throughput, low latency and reliability to remain competitive. For example, beyond the currently planned infrastructure to move up to 6 GHz, there is an additional 200 GHz of spectrum available at mm-wave frequencies that is under-utilized, and which could potentially support data rates in the region of 10 to 50 Gb per second.

Wide spectrum does not mean it is unlimited, and other services will also utilize the same, or neighboring, bands. If significant portion of spectrum is exclusively granted to a single independent mobile network operator, there will be inefficiency of spectrum utilization. An average consumer may utilize cm-waves with spectrum ranging from 3 to 30 GHz, and between 30 and 40 GHz (up to 300 GHz) as a mm-wave spectrum.

There is also spectrum sharing at 60 to 70 GHz for mission-critical services, which includes smart city infrastructure, healthcare, self-driving cars, and many other applications. Such services should preferably have access to a continuous high-speed, low-latency connection, and shared spectrum has the potential to help ensure that devices are always connected.

The present specification is concerned with phase shifters which may perform beamsteering for phased arrays, whilst reducing the complexity and costs of generating the required phase shifts between signals emitted from adjacent transducers (e.g. antennae). In particular, the present specification employs active matrix control of variable capacitances for beamforming. The phase shifters according to the present specification may be used with any transducers which emit/receive waves, but may be particular useful for radio transceivers.

The present specification also describes radio transceivers (or simply “radios”) which incorporate the phase shifters and may be configured for relaying radio signals, in particular radio signals exceeding 5 GHz used for data transmission in wireless communications networks (for example mobile/cell services). Amongst other features, the radio transceivers described herein may be compact and low profile, allowing for straightforward attachment to, or integration into, structures in a built environment. Radio transceivers according to the present specification may be particularly suitable for attachment to, or integration into, window glass.

These features allow radio transceivers to be added to structures in order to improve range, reduce blind spots, relay signals to the interior of structures or underground (for example metro transit systems), and so forth.

Outside of radio applications, the same technologies may also be applied to audio and/or ultrasound frequencies and devices.

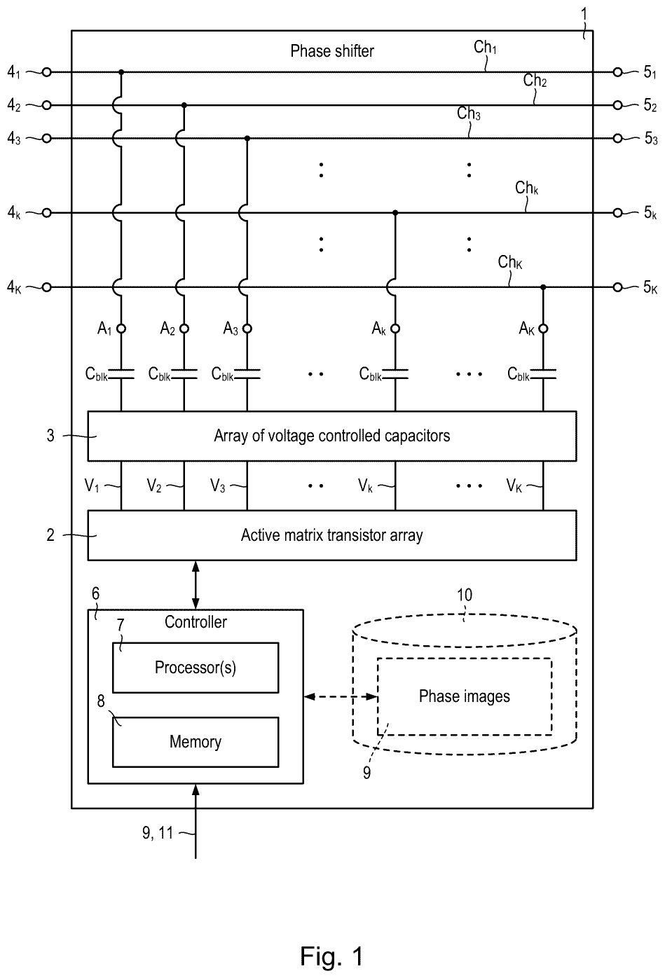

Referring also to FIG. 1, a phase shifter 1 is shown.

The phase shifter 1 includes an active matrix transistor array 2, an array 3 of voltage-controlled capacitors C(V) controlled by the active matrix transistor array 2 and a number K of signal channels Ch₁, Ch₂, . . . , Chₖ, . . . , Ch_{K} AC coupled to the bank 3 of voltage-controlled capacitors C(V) by respective capacitances C_{blk}.

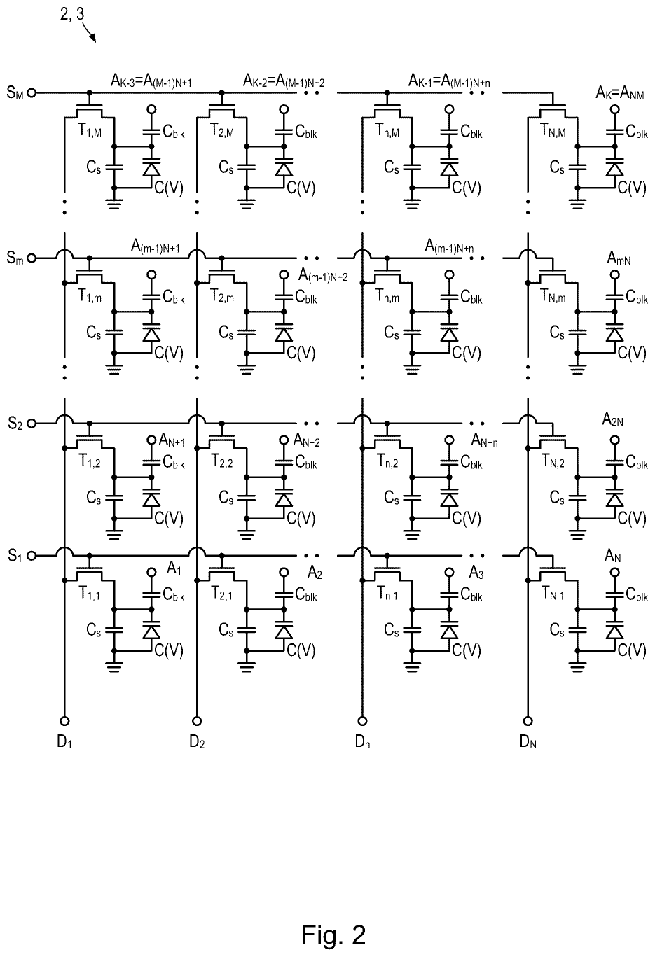

Referring also to FIG. 2, a circuit diagram is shown illustrating connections between the active matrix transistor array 2, the array 3 of voltage-controlled capacitors C(V) and the channels Ch₁, . . . , CH_{K}.

The active matrix transistor array 2 includes an M by N array of transistors T, with the transistor in the n^{th} column and m^{th} row denoted T_{n,m}. Each transistor T_{n,m} is configured to control a voltage bias across a corresponding storage capacitor Cs. A voltage-controlled capacitor C(V) of the array 3 is connected in parallel with each storage capacitor Cs. In this way, a voltage V_{n,m} applied across each storage capacitor Cₛ is controlled using the corresponding transistor T_{n,m}, and that voltage V_{n,m} then also provides the bias across the respective voltage-controlled capacitor C(V_{n,m}) to control its capacitance.

Each signal channel Chₖ has a first end 4ₖ and a second end 5ₖ, and is AC coupled to one or more voltage-controlled capacitors C(V) at a point between the first and second ends 4ₖ, 5ₖ, for example using a de-coupling capacitance C_{blk} as illustrated. Points labelled A₁, . . . , Aₖ, . . . , A_{K} are marked in FIGS. 1 and 2 for ease of correlating between the illustrations. The points A₁, . . . , A_{K} may correspond to physical electrical terminals for making electrical connections between the array 3 of voltage-controlled capacitances C(V) and the channels Ch₁, . . . , Chₖ. Although FIG. 2 has been drawn showing a 1:1 correspondence between transistors T_{n,m}, voltage-controlled capacitors C(V_{n,m}) and signal channels Chₖ, such that K=N·M, in general the number N·M of transistors T_{n,m} may be more than the number of voltage-controlled capacitors C(V), and similarly the number of voltage-controlled capacitors C(V_{n,m}) forming array 3 may exceed the number K of signal channels, i.e. N·M≥K. The points Aₖ may sometimes be equivalently referred to as points A_{n,m} when discussing the corresponding transistor T_{n,m}.

The phase shifter 1 is configured to control the phase shift φₖ applied to a given signal channel Chₖ by setting the voltages V_{n,m} across the storage capacitors Cₛ and corresponding voltage-controlled capacitors C(V_{n,m}) coupled to that signal channel Chₖ. Referring in particular to FIG. 2, a drive line Dₙ of a transistor T_{n,m} is set to a desired voltage V_{n,m}, and the gate of the transistor T_{n,m} is switched open using signal line Sm. In the exemplary phase shifter 1 shown in FIG. 1, the active matrix transistor array 2 is controlled by a controller 6 which includes one or more digital electronic processors 7, memory 8 and non-volatile storage (not shown) storing program code. The controller 6, or the functions of the controller, may be provided by a microcontroller, a field programmable gate array, an application specific integrated circuit (ASIC), a central processing unit (CPU) of a device incorporating the phase shifter 1, and so forth.

The voltage-controlled capacitors C(V_{n,m}) may be provided by any device having a capacitance which may be varied as a function of a voltage input and/or applied bias across the device. Examples of voltage-controlled capacitors C(V_{n,m}) include varactor diodes (sometimes referred to as “varicaps”), ferroelectric capacitors, or any other devices based at least partly on geometric effects such as modulation of the width of a depletion layer, modulation of dielectric constant, and so forth. Depending on the type of voltage-controlled capacitors C(V_{n,m}), the voltage V_{n,m} across a storage capacitor may be applied as a reverse bias to a diode-based voltage-controlled capacitors C(V_{n,m}) such as a varactor

Each signal channel Ch₁, . . . , Ch_{K} may be a single conductor, but more typically will be a transmission line, for example a micro-strip transmission line, a twisted pair of wires, a co-axial cable and so forth. For large numbers K of channels, micro-strip transmission lines may be most practical. Each signal channel Chₖ may be coupled to a single voltage-controlled capacitor C(V_{n,m}), as shown in FIG. 2. In this case, the total effective capacitance C_{eff} coupled to the signal channel Chₖ is:

$${C}_{eff} = \frac{{C}_{b l k} ( {C}_{s} + C ( {V}_{n , m} ) )}{{C}_{b l k} + {C}_{s} + C ( {V}_{n , m} )} \qquad ( 1 )$$

With the storage capacitance Cₛ adding in parallel with the voltage-controlled capacitance C(V_{n,m}), and their sum combining in series (reciprocally) with the de-coupling capacitance C_{blk}. It may be observed that in order to achieve the widest possible range of phase shifts φₖ for a given range of capacitance AC achievable using a given voltage-controlled capacitance C(V_{n,m}), the contribution of the variable capacitance to the effective capacitance C_{eff} should be maximized. This is done by selecting the storage capacitance Cₛ to be as small as possible, and selecting the de-coupling capacitance C_{blk} to be significantly larger (e.g. ten times or more) than sum of the storage capacitance Cₛ and the voltage-controlled capacitance C(V_{n,m}). In practice, the voltage V_{n,m} across the storage capacitance Cₛ and the voltage-controlled capacitance C(V_{n,m}) will decay over time due to leakage currents, and will require periodic refreshing. The limitation on the minimum size of the storage capacitance Cₛ is that it should be large enough to maintain the bias voltage V_{n,m} across the voltage-controlled capacitance C(V_{n,m}) within an acceptable range for the period between addressing the transistor T_{n,m}. Depending on leakage currents, in some cases the storage capacitance Cₛ may be larger than the voltage-controlled capacitance C(V_{n,m}) (for high leakage), whereas the storage capacitance may be omitted entirely if the leakage currents through the voltage-controlled capacitance C(V_{n,m}) are low enough. In this context, leakage currents are low enough if a voltage V_{n,m} set during addressing of a transistor T_{n,m} may be maintained within a desired range until the next time that transistor T_{n,m} is addressed.

If a total shift in coupled effective capacitance is needed than can be provided by a single voltage-controlled capacitance C(V_{n,m}), then two or more may be coupled to a signal channel Chₖ in parallel.

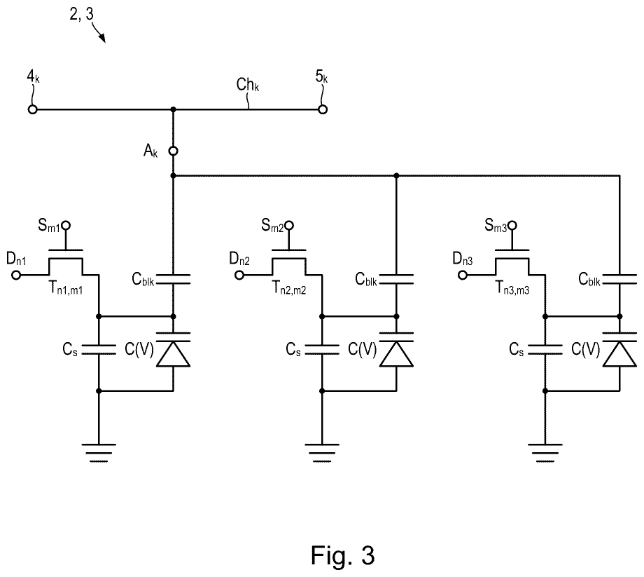

Referring also to FIG. 3, an example of coupling a single signal channel Chₖ to two or more voltage-controlled capacitances C(V_{n,m}) is illustrated.

Voltage controlled capacitances C(V_{n,m}) corresponding to three different transistors T_{n1,m1}, T_{n2,m2}, T_{n3,m3} are coupled in parallel to the signal channel Chₖ. The transistors T_{n1,m1}, T_{n2,m2}, T_{n3,m3} may in principle be at any locations in the active matrix transistor array, although in practice to simplify routing of connections the transistors T_{n1,m1}, T_{n2,m2}, T_{n3,m3} are preferably adjacent in the array 2. De-coupling capacitances C_{blk} prevent DC levels from interfering amongst the voltage-controlled capacitances C(V_{n,m}) and between the voltage-controlled capacitances C(V_{n,m}) and the signal channel Chₖ. Each branch has an effective capacitance as Equation (1), so that for the parallel coupled configuration of FIG. 3, the overall coupled capacitance C_{eff} becomes:

$${C}_{eff} = \frac{{C}_{blk} ( {C}_{s} + C ( {V}_{n 1 , m 1} ) )}{{C}_{blk} + {C}_{s} + C ( {V}_{n 1 , m 1} )} + \frac{{C}_{blk} ( {C}_{s} + C ( {V}_{n 2 , m 2} ) )}{{C}_{blk} + {C}_{s} + C ( {V}_{n 2 , m 2} )} + \frac{{C}_{blk} ( {C}_{s} + C ( {V}_{n 3 , m 3} ) )}{{C}_{blk} + {C}_{s} + C ( {V}_{n 3 , m 3} )} \qquad ( 2 )$$

If the de-coupling capacitances are selected to be significantly larger (e.g. ten times or more) as described hereinbefore, such that each denominator may be approximated as C_{blk}, then the overall coupled capacitance C_{eff} may be approximated as:

$${C}_{eff} \approx 3 {C}_{s} + C ( {V}_{n 1 , m 1} ) + C ( {V}_{n 2 , m 2} ) + C ( {V}_{n 3 , m 3} ) \qquad ( 3 )$$

Whilst the relative size of the possible capacitance shift will be unaffected, the absolute range of capacitance variation may be increased by a factor of three. Again, storage capacitors Cₛ may be omitted if the leakage currents are sufficiently low.

In general, the coupled voltage-controlled capacitances C(V_{n,m}) may be set independently of one another, though a pair, or all three may be set to the same voltage V_{n,m}. In the special case that all three are to be set to the same voltages, i.e. V_{n1,m1}=V_{n2,m2}=V_{n3,m3}, the configuration of FIG. 3 may be simplified by connecting multiple voltage-controlled capacitances C(V_{n,m}) in parallel with a single storage capacitance Cₛ.

The example in FIG. 3 shows coupling to three voltage-controlled capacitances C(V_{n,m}) in parallel, but may be adapted for connecting fewer (i.e. two), or more (i.e. four or more) voltage-controlled capacitances C(V_{n,m}) in parallel.

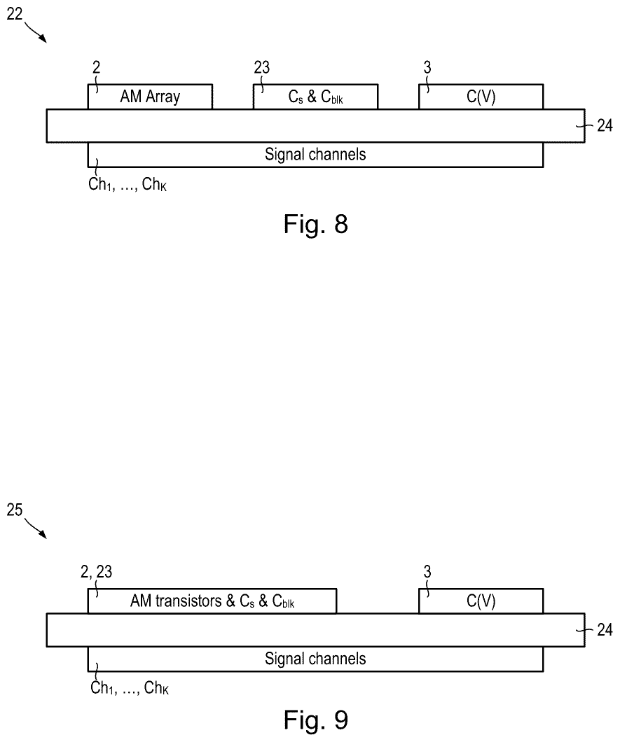

Each transistor T_{n,m} providing the active matrix transistor array 2 may be of any type, although for practicality it is preferably that all transistors T_{n,m} providing the active matrix transistor array 2 are substantially identical and formed on a common substrate. When the transistors T_{n,m} providing the active matrix transistor array 2 take the form of thin-film transistors, for example defined in amorphous silicon layers, this may be advantageous in terms of being able to use existing TFT-on-glass production lines used for computer displays and the like. As described hereinafter in relation to FIGS. 8 to 14, this may also allow some or all of the other components of the phase shifter 1 (and a radio 14 including the phase shifter 1) to be formed at the same time and/or on the same substrate as the active matrix transistor array 2, providing a high degree of integration.

### Phase Images

Referring again to FIG. 1, the phase shifter 1 may be configured to receive or generate phase images 9.

Each pixel of a phase image 9 corresponds to a transistor T_{n,m} of the active matrix transistor array 2, and the value/intensity of that pixel corresponds to a voltage V_{n,m} for application to the associated storage capacitor Cₛ. For example, denoting the pixel of the phase image 9 corresponding to transistor T_{n,m} as P_{n,m}, the pixel may store a value, for example 0≤P_{n,m}≤255, which may be converted into a fraction P_{n,m}/255 of a maximum bias voltage Vₘₐₓ which may be applied to the voltage-controlled capacitors C(V_{n,m}) (and parallel connected storage capacitors Cₛ if included).

In this way, the phase shifter 1 (for example the controller 6) may simply take the phase image 9 and set the voltage V_{n,m} for each storage capacitor Cₛ according to the respective pixel P_{n,m} of the phase image 9. In the example where 0≤P_{n,m}≤255, the voltages may be set as V_{n,m}=Vₘₐₓ(P_{n,m}/255). Phase images 9 may be stored in the internal non-volatile storage (not shown) of the controller 6, in a non-volatile storage device 10 separate from the controller 6, which is also component of the phase shifter 1, or may be received by the phase shifter 1, for example from a CPU (not shown) of a device incorporating the phase shifter 2. In some implementations, the controller 6 may generate the phase image 9 on demand in response to receiving a command 11 indicating a desired beamforming angle/direction. For the latter implementation, the phase shifter 1 (or controller 6) should also store or receive information detailing the geometry (relative positions) and optionally emission patterns of an array of transducers being driven as a phased array via the phase shifter 1.

The use of phase images 9 may allow use or adaptation of control circuits already developed for use in active matrix displays. Such control circuits are already capable of controlling voltages for millions of pixels of a display.

The phase image 9 may alternatively be described as a “hologram”, where herein the term “hologram” may also be used to describe a 3D wave pattern formed by interference between signals phase shifted by different amounts by the phase shifter 1. In other words, the term “hologram” may be applied to the phase image 9, to the resulting phase shifted electrical signals after transmission through the phase shifter 1 and/or a wave pattern emitted based on the phase shifted electrical signals.

### In-Channel Processing

In addition to the primary function of coupling one or more variable and controlled capacitance C(V_{n,m}) to each signal channel Chₖ, the phase shifter 1 may also support additional signal processing functions.

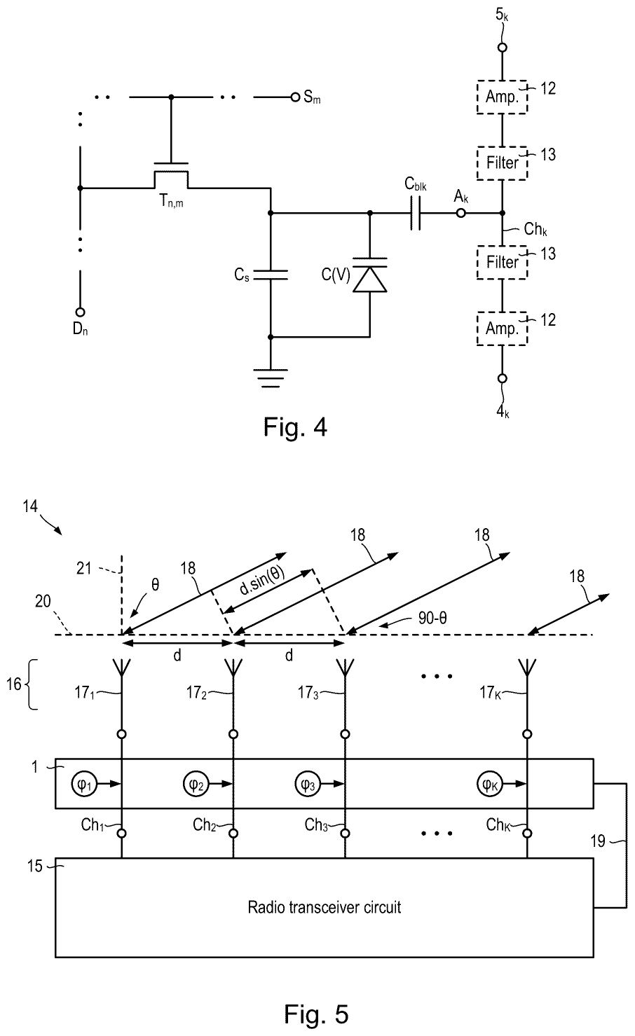

Referring also to FIG. 4, a signal channel Chₖ is shown along with a coupled voltage-controlled capacitance C(V_{n,m}) and the relevant portion of the active matrix transistor array 2.

In the example shown in FIG. 4, a single voltage-controlled capacitance C(V_{n,m}) is coupled to the kth signal channel Chₖ via a connection point Aₖ (which may alternatively by denoted A_{n,m}). However, in other examples, multiple voltage-controlled capacitances C(V_{n,m}) may be coupled to the kth signal channel Chₖ as shown in FIG. 3. As described hereinbefore, the connection point Aₖ may be a physical terminal, but the decoupling capacitance C_{blk} could instead by directly connected to the signal channel Chₖ.

The, or each, signal channel Chₖ may optionally include one or more amplifiers 12 between the respective first 4ₖ and second 5ₖ ends. Amplifiers 12 may be placed before and/or after the point of coupling to the voltage-controlled capacitor(s) C(V_{n,m}). Amplifiers 12 may be of any suitable type to provide signal conditioning for the application in which the phase shifter is deployed. For example, if being used for beamforming of a transmitting array, some or all signal channels Chₖ may include an amplifier 12 in the form of a power amplifier to drive a corresponding transducer. Alternatively, if being used for beamforming on a receiving/detecting array, some or all signal channels Chₖ may include an amplifier 12 in the form of a low-noise amplifier for amplifying a received signal.

Similarly the, or each, signal channel Chₖ may optionally include one or more filters 13 between the respective first 4ₖ and second 5ₖ ends. Filters 13 may be placed before and/or after the point of coupling to the voltage-controlled capacitor(s) C(V_{n,m}). Filters 13 may be active or passive types. When the signal channels Chₖ take the form of transmission lines, one or more filters 13 may be integrally formed with the transmission line, for example, as a distributed element filter, a film bulk acoustic resonator (FBAR), a metamaterial filter and so forth.

Some, or all, of the signal channels CHₖ may be switchable between two or more filters 13, each filter 13 having a distinct bandwidth. Signal channels Chₖ may be switchable between two or more filters 13 using transistors (not shown), which may be separate from the active matrix transistor array 2, but which preferably would be integrally formed with the active matrix transistor array 2 to reduce complexity and avoid long range interconnects.

### Radio Transceiver

A phase shifter 1 may be configured to apply phase shifts φₖ to radio frequency signals.

Referring also to FIG. 5, a radio 14 including the phase shifter 1.

The radio 14 includes a radio transceiver circuit 15 connected via the phase shifter 1 to an array 16 including a number K of antennae 17 (first antennae). Each antenna 17ₖ is connected to the radio transceiver circuit 15 via a respective signal channel Chₖ of the phase shifter 1.

The phase shifter 1 is configured for radio frequency signals having carrier frequencies between and including 5 GHz and 300 GHz. This configuration is primarily provided by the size and range of variable capacitances C(V), which need to be selected to provide phase changes φ spanning as much as possible of the range 0 to π, given a desired operational frequency range, spacing d of antennae 17ₖ, 17ₖ₊₁, and so forth.

The radio frequency transceiver circuit 15 is configured to control the array 16 of antennae 17₁, . . . , 17_{K} as a (first) phased array by performing beamforming of radio signals 18 received by and/or transmitted from the antennae 17₁, . . . , 17_{K} using the phase shifter 1. For example, the radio transceiver 15 circuit sends control signals 19 to the phase shifter 1. The control signals 19 may take any suitable form in dependence on the configuration of the phase shifter 1, including sending phase images 9 and/or instructions 11. As one example, the instructions 11 may identify a desired beamforming angle θ, and the phase shifter 1 may use a look-up table to retrieve a corresponding phase image 9 (or corresponding voltages V_{n,m} stored in any machine readable format).

The antennae 17₁, . . . , 17_{K} forming the array 16 may be disposed to be substantially co-planar. The presently described phase shifters 1 may be particularly useful when combined with planar antennae aligned to correspond to (or even integrated with as described hereinafter) the component transistors T_{n,m} and voltage-controlled capacitors C(V_{n,m}) of the phase shifter 1. This is because the number of antennae in such an array may be very large, and the phase shifters 1 described herein may be scaled relatively easily to large numbers K of antennae 17ₖ. For example, K could be hundreds of thousands, or even millions, and it may be impractical to define such numbers of antennae 17ₖ other than by patterning them as planar antennae (for example co-located with the respective transistors T_{n,m} and voltage-controlled capacitors C(V)).

For antennae 17₁, . . . , 17_{K} spaced at intervals d along a plane 20, adjacent antennae 17ₖ, 17_{k±1} will receive signals 18 incident from an angle θ to a normal 21 to the plane with a path length difference of d·sin(θ). To beamform for receiving/transmitting at the angle θ, the radio transceiver circuit 15 controls the phases φ₁, . . . , φ_{K} introduced to each signal channel Ch₁, . . . , Ch_{K} to compensate for the path length differences d·sin(θ). Of course, the precise path length differences that need compensation will of course depend on the geometry of the array 16. Although the examples described have the antennae 17ₖ arranged on a plane, this is not necessary, and in general the antennae 17ₖ may adopt a three-dimensional arrangement (and the phase shifter 1 may be calibrated for the appropriate path length differences).

The radio frequency transceiver circuit 15 may be configured as a radio receiver, transmitter, or both (time multiplexed or concurrently). The radio 14 may be used as a base station of a wireless communications network, or to relay signals 18 at part of a wireless communications network,

Although shown in FIG. 5 with the number of antennae 17 being equal to the number of signal channels Chₖ, this is not essential and the number of first antennae 17 may be less than the number K of signal channels Chₖ of the phase shifter 1 (although this is not preferred for optimal efficiency).

Whilst each signal channel Chₖ may be driven/received by a corresponding port of the radio transceiver circuit 15, this may become impractical as the number K of signal channels Chₖ is increased. It is also unnecessary, since the introduction of a different phase φₖ into each signal channel Chₖ by coupling to the connected voltage-controlled capacitor(s) C(V) permits for all signal channels Chₖ to be driven/receive in phase, with beamforming entirely provided by the introduced phases (Pk. At the other extreme from a port per signal channel Chₖ, all of the signal channels Ch₁, . . . , Ch_{K} may be driven/received by a single port of the radio transceiver circuit 15.

In some implementations, beamforming may be accomplished using a hybrid of conventional methods and the phase shifter 1. For the purposes of explanation, consider an array of K=100 antennae 17₁, . . . , 17₁₀₀ and corresponding signal channels Ch₁, . . . , Ch₁₀₀. The radio frequency transceiver circuit 15 may have ten ports for driving/receiving signals, and may be configured to drive/receive from each with a respective first phase difference Ψ₁, . . . , Ψⱼ, . . . , Ψ₁₀. The total phase difference applied to a signal in the first group of ten signal channels Ch₁, . . . , Ch₁₀ will then be the sum Ψ₁+φₚ (for 1≤k≤10), and so forth for each group of ten. In this way, the radio transceiver circuit 15 may provide coarse beamforming, whilst the phase shifter 1 provides a second layer of fine beamforming. This may permit beamforming a larger number of antennae 17 then would be possible using the radio transceiver circuit 15 alone, whilst also beamforming to wider range of angles θ than would be possible using the phase shifter 1 alone.

Whilst not necessary, it may be advantageous if the antennae 17 are arranged in an array 16 which conforms to the active matrix array 2 and the array of voltage-controlled capacitors C(V).

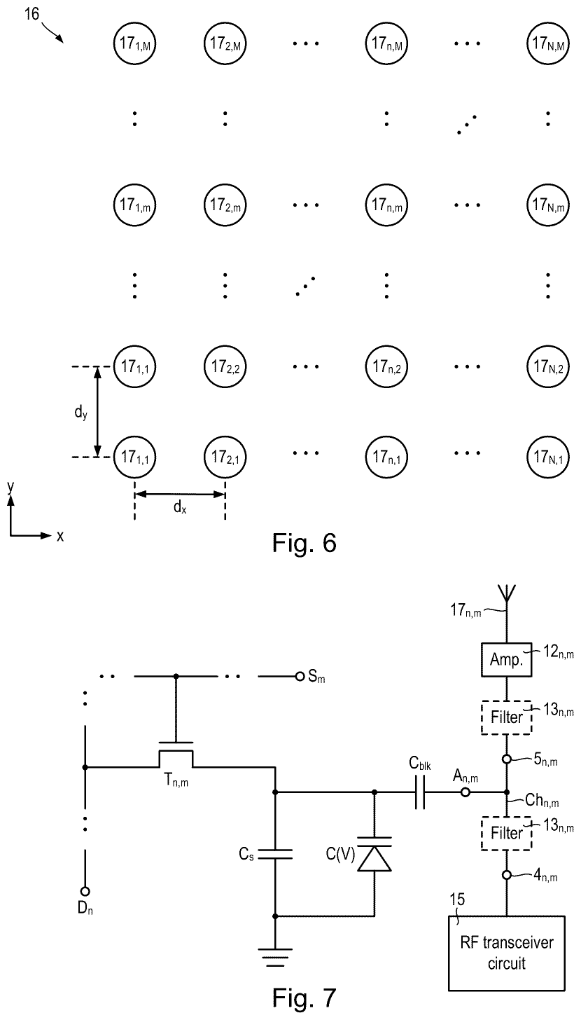

Referring also to FIG. 6, an exemplary array 16 of antennae 17 is shown.

The geometry of the array 16 of antennae 17 correspond to the geometry of the active matrix transistor array 2. The array 16 includes an antenna 17_{n,m} corresponding to each transistor T_{n,m}, and the antennae 17_{n,m} form a rectangular array with spacing dx along a first direction x and d_{y} along a second, perpendicular direction y.

Referring also to FIG. 7, a portion of the phase shifter 1 is shown, connecting the antenna 17_{n,m} of the nth column and m^{th} row to the radio frequency transceiver circuit 15 via a respective signal channel Ch_{n,m}.

Although a 1:1 mapping of voltage-controlled capacitors C(V_{n,m}) and signal channels Ch_{n,m} is shown in FIG. 7, as described in relation to FIG. 3, each signal channel Ch_{n,m} may instead be coupled to two or more voltage-controlled capacitors C(V). In such a configuration the numbers of transistors T and antennae 17 will not match, and instead each antenna 17 will be positioned to correspond to a group of transistors T controlling the corresponding voltage-controlled capacitors C(V).

Each antenna 17_{n,m} is connected to the respective signal channel Ch_{n,m} of the phase shifter via 1 one or more amplifiers 12_{n,m}. Although shown as external to the signal channel Ch_{n,m} and phase shifter 1 in FIG. 7, in other examples the amplifiers 12_{n,m} may integrated as part of the signal channel Ch_{n,m} and/or phase shifter 1 (see FIG. 4).

When used for reception of radio signals 18, the amplifiers 12_{n,m} preferably take the form of low noise amplifiers, or equivalent, for amplifying detected signals. When used for transmission of radio signals 18, the amplifiers 12_{n,m} preferably take the form of power amplifiers, or equivalent, to boost the signal prior to transmission by respective antennae 17_{n,m}. There are a number of options when the radio 14 is used for both receiving and transmitting (transceiver function, e.g. for relaying signals). One option is that each antenna 17_{n,m} may be connected to the respective signal channel Ch_{n,m} of the phase shifter 1 via a path (not shown) which is switchable between a low noise amplifier in a receive mode and a power amplifier in a transmit mode. The switching may be implemented using additional transistors integrally formed with the transistors T_{n,m} making up the active matrix transistor array 2. The radio 14 may then time multiplex receiving and transmitting functions, using one set of signal channels Ch₁, . . . , Ch_{N,M}.

In an alternative implementation, a subset of the antennae 17_{n,m} may be connected to the respective signal channels Ch_{n,m} of the phase shifter 1 via one or more low noise amplifiers 12_{n,m} for reception, whilst the complement of the subset of the antennae 17_{n,m} are connected to the respective signal channels Ch_{n,m} of the phase shifter 1 via one or more power amplifiers 12_{n,m} for transmission. For example, the even rows m and columns n may correspond to receive antennae 17_{n,m}, and the odd rows m and columns n may correspond to transmit antennae 17_{n,m}.

Similarly, each antenna 17_{n,m} may be connected to the respective signal channel Ch_{n,m} of the phase shifter via 1 one or more filters 13_{n,m}, which may be external and/or internal to the phase shifter 1 (e.g. integrated with the respective signal channel Ch_{n,m}).

### Integration of Radio Components

Referring also to FIG. 8, a first integrated configuration 22 of radio 14 components (hereinafter “first configuration”) is shown.

In the first configuration 22, the active matrix transistor array 2, T_{n,m}, a bank 23 of storage capacitors Cₛ and decoupling capacitors C_{blk}, and the array 3 of voltage-controlled capacitors C(V) are all supported by a common substrate 24. The signal channels Ch₁, . . . , Ch_{K} are also supported by the common substrate 24. For example, FIG. 8 shows the signal channels Ch₁, . . . , Ch_{K} supported on an opposite face of the common substrate 24 to the voltage-controlled capacitors C(V), enabling minimal length connections using vias (not shown) formed through the thickness of the common substrate 24.

The common substrate 24 may take the form of a flexible film or sheet, for example a polymer such as polycarbonate (PC), polyimide (PI), polyethylene terephthalate (PET), polyethylene naphthalate (PEN), cyclo-olefin polymer (COP), or any other polymer having sufficient mechanical strength to support the circuitry. In other examples, the common substrate 24 may take the form of a multi-layer printed circuit board. Another option for the common substrate 24 is glass, which may be advantageous because it may allow techniques and/or production facilities used in display manufacture to be adapted/re-purposed for production of the phase shifter 1 (optionally including further components of the radio 14 such as antennae 17).

The common substrate 24 may be transparent, for example having a minimum transmission of 50% for visible wavelengths (e.g. a range between 380 nm and 750 nm).

Although not shown in FIG. 8, an array 16 of planar antennae 17_{n,m} may be formed on a second substrate (not shown) aligned overlying the common substrate 24. Alternatively, an array 16 of planar antennae 17_{n,m} may be supported on the same common substrate 24, interspersed with the components of the phase shifter 1.

Electrical components of the phase shifter 1, may be supported, deposited, patterned and/or integrated on one or both sides of the common substrate 24. Electrical components of the phase shifter 1 may include, for example, the transistors T_{n,m} of the active matrix transistor array 2, the storage capacitors Cₛ, the decoupling capacitors C_{blk}, the voltage-controlled capacitors C(V_{n,m}) of the array 3, signal channels Chₖ (e.g. transmission lines) and so forth. Electrical components of the phase shifter 1 may also include one or more amplifiers 12, filters 13 and so forth. Additional components of the radio 14, for example the array 16 of antennae 17, the radio frequency transceiver circuit 15 and so forth, may additionally be supported, deposited, patterned and/or integrated on one or both sides of the common substrate 24. Interconnections between electrical components of the phase shifter 1 and/or the radio 14 supported on opposite faces of the common substrate 24 may be provided using through vias.

The common substrate 24 may take the form of a laminate of multiple layers, each layer of which may be formed of any of the materials mentioned herein for the non-laminate common substrate, for example one or more layers of glass, plastic and/or adhesive. When the common substrate 24 is a laminate, one or more electrical components of the phase shifter 1 (and/or the radio 14) may be supported, deposited, patterned and/or otherwise integrated on and/or within one or more internal layers of the laminate common substrate 24. A common substrate 24 in the form of a laminate may include one or more conductor layers which may be internal (i.e. between the first and second faces) and/or external (i.e. supported on the first and/or second faces).

The active matrix transistor array 2 may be integrated on and/or in the common substrate 24, for example the common substrate 24 may be a glass or other substrate compatible with thin-film transistor (TFT) fabrication methods, and the active matrix transistor array 2 may be provided by TFTs. Alternatively, the active matrix transistor array may be a stand-alone component (for example a semiconductor die) which is flip-chip bonded to the common substrate 24 (more specifically, to conductive tracks and/or other components supported thereon). Similarly, any or all of the storage capacitors Cₛ, decoupling capacitors C_{blk}, the voltage-controlled capacitances C(V) and any other component of the phase shifter 1 or radio 14 may be integrated on and/or in the common substrate 24, or may instead by separate components which are bonded (e.g. flip-chip bonded) to the common substrate 24.

The signal channels Chₖ may be formed on the common substrate 24 (or on an internal layer of a laminate) by depositing and patterning a conductive layer. Preferably, the signal channels Chₖ are formed as microstrip transmission lines. Although shown supported on one side of the common substrate 24, the signal channels Chₖ may be formed on both sides, connected by vias (not shown). When used for connecting between microstrip lines supported on opposed faces of the common substrate 24 and other microstrip lines and/or other components, vias should preferably be impedance matched to the microstrip lines. Compared to, for example, radiative transfer or capacitive coupling between opposed faces of the common substrate 24, such physical connections do not require that the common substrate 24 is formed from a material or materials having low dielectric loss properties. Though not required, materials having low dielectric loss properties may still be used.

When one or more electrical components of the phase shifter 1 (or radio 14) are flip-chip bonded to the common substrate 24, such components may be flip-chip bonded to the common substrate 24 in accordance with the Heterogeneous Integration Roadmap, HIR. The Heterogeneous Integration Roadmap (HIR) is a set of guidelines developed for silicon systems-in-package (SiP) technologies. HIR may refer to, for example, the guidelines set out in the publication of the HIR 2019 edition.

If the phase shifter 2 includes filters 13, the filters 13 may additionally be supported by the common substrate 24. For example, filters 13 may be integrated into the signal channels Chₖ in the form of one or more of distributed element filters, film bulk acoustic resonators, FBARs, thin-film bulk acoustic resonators, TFBAR, metamaterial filters and so forth. Metamaterial filters suitable for use in the phase shifter 1 for a radio 14 include, without being limited to, metamaterial filters described in “Metamaterial Structure Inspired Miniature RF/Microwave Filters”, Abdullah Alburaikan, PhD Thesis (2016), The University of Manchester, https://www.escholar.manchester.ac.uk/uk-ac-man-scw:305308, (see in particular pages 56 onwards). Filters may be formed directly on the common substrate 24 (or internal layers of a laminate), or alternatively one or more stand-alone filters/filter banks may be attached (e.g. flip-chip bonded) to the common substrate 24.

As described hereinbefore, some (or all) of the signal channels Ch₁, . . . , Ch_{K} may be switchable between two or more filters 13, each filter 13 having a distinct frequency bandwidth. Transistors used for switching (not shown) may be supported on the common substrate 24, but preferably are integrally formed with the active matrix transistor array 2. Switching between filters 13 in this way may enable the radio 14 to be switchable between different frequency bands. It should be noted that different sets of phase images 9 may be used (or generated) for different frequency bands (since a given physical path difference corresponds to a different phase).

The common substrate may incorporate or support a heat spreader layer (not shown). The heat spreader layer (not shown) may be integrally formed with the common substrate 24, incorporated during a heterogeneous integration fabrication process, deposited over the common substrate 24, and so forth. When included, the heat spreader layer (not shown) may enable operation at higher power and/or using a higher density of electrical components and interconnects without requiring a fan or other cooling method. For example, a ground plane layer (not shown) for the phase shifter 2 may be formed from copper (or other material with high electrical and heat conductance) and additionally serve as a heat spreader layer.

If the phase shifter 2 includes amplifiers 12, those amplifiers 12 may additionally be supported by the common substrate 24. For example, the phase shifter 1 may include one or more amplifiers in the form of CMOS amplifiers supported by the common substrate 24.

Referring also to FIG. 9, a second integrated configuration 25 of radio 14 components (hereinafter “second configuration”) is shown.

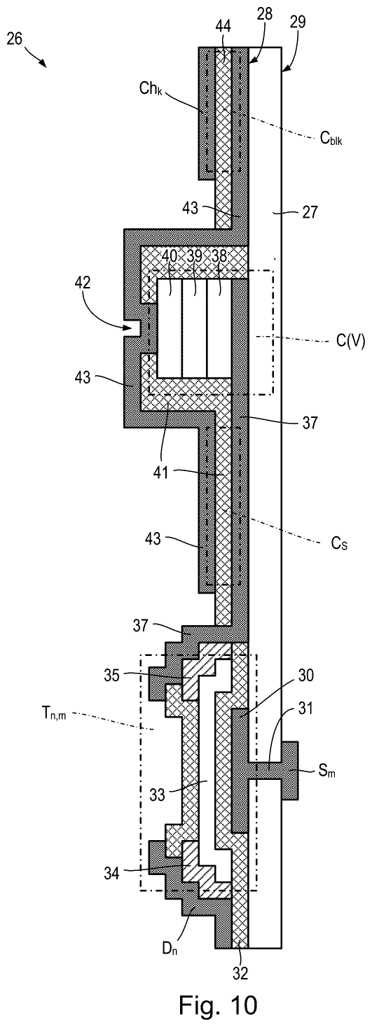

The second configuration 25 is substantially the same as the first configuration 22, except that the bank 23 of capacitors Cₛ, C_{blk} is additionally integrated as a single component with the active matrix transistor array 2. As discussed further in relation to FIG. 10, additional conductors may be arranges and patterned to form capacitors within a structure defining transistors T_{n,m}.

### Integrated Device Structure

Referring also to FIG. 10, the active matrix transistor array 2, array 3 of voltage-controlled capacitances C(V) and signal channels Chₖ may be formed in an integral device structure 26.

FIG. 10 shows only a portion of an integral device structure 26, corresponding to a single transistor T_{n,m} and associated signal channel Chₖ. An integral device structure 26 may be formed onto a single semiconductor die, or directly onto a common substrate 24. For example, a TFT fabrication process may be adapted to produce an integral device structure 26 onto a common substrate 24 in the form of a glass substrate.

A substrate 27, which may in some examples by the common substrate 24, has a first face 28 and a second face 29. An addressing (scan) line Sm is supported on the second face 29, and connected to a gate electrode 30 of a corresponding transistor T_{n,m} by a through via 31. The gate electrode 30 is covered over by a first dielectric region 32, which is in turn covered by a semiconductor layer 33. The semiconductor layer 33 may be n-type or p-type. Regions 34, 35 of the semiconductor layer 33 are oppositely doped to the bulk to form source and drain for the transistor T_{n,m}. The semiconductor layer 33 and one or more of the source and drain 34, 35 may be covered by a second dielectric layer 36. One end 34 of the transistor T_{n,m} channel is contacted by a drive (data) line Dₙ, whilst the other end 35 is connected to a first conductive interconnect 37 which extends along the first face 28 to provide one electrode each of a storage capacitor Cₛ and a voltage-controlled capacitance C(V).

The first conductive interconnect 37 supports, in order, an n-doped semiconductor layer 38, and intrinsic semiconductor layer 39 and a p-doped semiconductor layer 40. A third dielectric layer 41 covers a region of the first conductive interconnect 37 corresponding the storage capacitance Cₛ and the semiconductor layers 38, 39, 40. Overlying the semiconductor layers 38, 39, 40, a gap 42 is formed in the third dielectric layer 41, and a second conductive interconnect 43 is formed over the third dielectric layer to complete the storage capacitance Cₛ and voltage-controlled capacitor C(V), and extending along the substrate to provide an electrode of the decoupling capacitance C_{blk}.

A region of the second conductive interconnect 43 not corresponding to the storage capacitance Cₛ or the voltage-controlled capacitance C(V) is covered by a fourth dielectric layer 44. The signal channel Chₖ (for example one conductor of a microstrip transmission line) is formed over the fourth dielectric layer 44, to complete the decoupling capacitance C_{blk}.

Any or all of the capacitances Cₛ, C(V), C_{blk} need not be formed integrally with the transistors T_{n,m}, and may instead by separate component(s), for example mounted to the second face 29 and connected using additional through-hole vias (not shown). In particular, the decoupling capacitance C_{blk} is preferably larger than the sum of storage and variable capacitances Cₛ+C(V), and this will typically require the decoupling capacitance C_{blk} to be formed across a larger area. This may be avoided using a separate decoupling capacitance C_{blk}.

Preferably, the integral device structure 26 may be made using usual methods and materials known in the field of thin-film transistor (TFT) active matrix displays. For example, the substrate 27 (which may be the common substrate 24) may be glass, whilst amorphous silicon/silicon oxide are used for semiconducting layers and dielectric layer respectively. Conductive layers may be deposited using a metal, for example aluminum.

In some examples the antennae 17 may be supported on a separate substrate (not shown) and connected to the signal channels Chₖ using any suitable type of electrical interconnection.

Parasitic capacitances and inductances generally scale with the length of an interconnection, therefore, it may be helpful to minimize the physical separation of the signal channels Chₖ and corresponding antennae 17ₖ. Minimum interconnect distance may be obtained if the antennae 17ₖ are supported on the same substrate (e.g. the common substrate 24 or the substrate 27) as the signal channels Chₖ. For example, each antenna 17ₖ may take the form of a planar antenna terminating the respective signal channel Chₖ. In the case of the integral device structure, planar antennae 17k may be formed on either the first or second faces 28, 29 of the substrate 27 and positioned proximate to the corresponding transistor T_{n,m} and voltage-controlled capacitance C(V_{n,m}). This is not problematic for a layout, since the sizes and spacing of antennae 17 for high frequency radio (e.g. mm-wave) are orders of magnitude larger than the pixel sizes routinely fabricated for display purposes. Indeed, this leaves plenty of space for additional transistors (not shown), for example to switch between filters 13, provide amplifiers 12 and so forth.

Forming and/or supporting antennae 17ₖ on a common substrate 24, 27 with the phase shifter 1 may reduce the costs and complexity of manufacturing a radio 14, as well as reducing the physical size of the radio.

Optionally one, some or all components of the radio frequency transceiver circuit 15 may be integrated on the same substrate, or within the same laminate as the phase shifter 1 (and optionally the antennae 17), for example the common substrate 24. Such components may be flip-chip bonded to a substrate or laminate supporting or including the phase shifter 1 (and optionally the first antennae 17), for example the common substrate 24.

### Examples of Planar Antennae

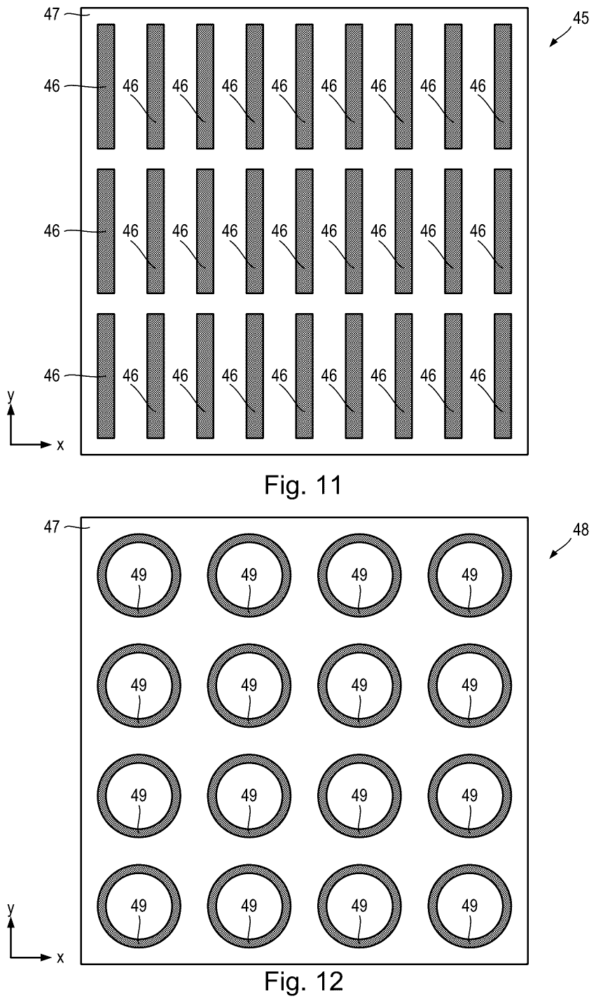

Referring also to FIG. 11, a first exemplary antenna array 45 is shown (hereinafter “first antenna array”).

The first antenna array 45 is a rectangular array of rectangular planar antennae 46, each of which may provide an array 16 of antennae 17 for the radio 14. The rectangular planar antennae 46 are supported on a substrate 47. The substrate 47 may be transparent to facilitate mounting the first antenna array 45 on a window of a vehicle, building and so forth. The substrate 47 may be the common substrate 24 and/or the substrate 37 of the integral device structure 26.

Although shown as rectangular, the rectangular planar antennae 46 may be square. Although shown in a rectangular array 45, the rectangular planar antennae 46 may be organized according to any (lattice) type or shape of array. Although a three by nine array 45 is shown in FIG. 11, an array 45 of the rectangular planar antennae 46 may include any numbers M, N of rows and/or columns.

Referring also to FIG. 12, a second exemplary antenna array 48 is shown (hereinafter “second antenna array”).

The second antenna array 48 is a square array of ring (or “loop”) planar antennae 49, each of which may provide an array 16 of antennae 17 for the radio 14. The ring planar antennae 49 are supported on the substrate 47 in the same way as the rectangular antennae 46.

Although shown as circular, the ring planar antennae 49 may take any shape, for example elliptical, square and so forth. Although shown in a square array 48, the ring planar antennae 49 may be organized according to any (lattice) type or shape of array. Although a four by four array 48 is shown in FIG. 12, an array 48 of the ring planar antennae 49 may include any numbers M, N of rows and/or columns.

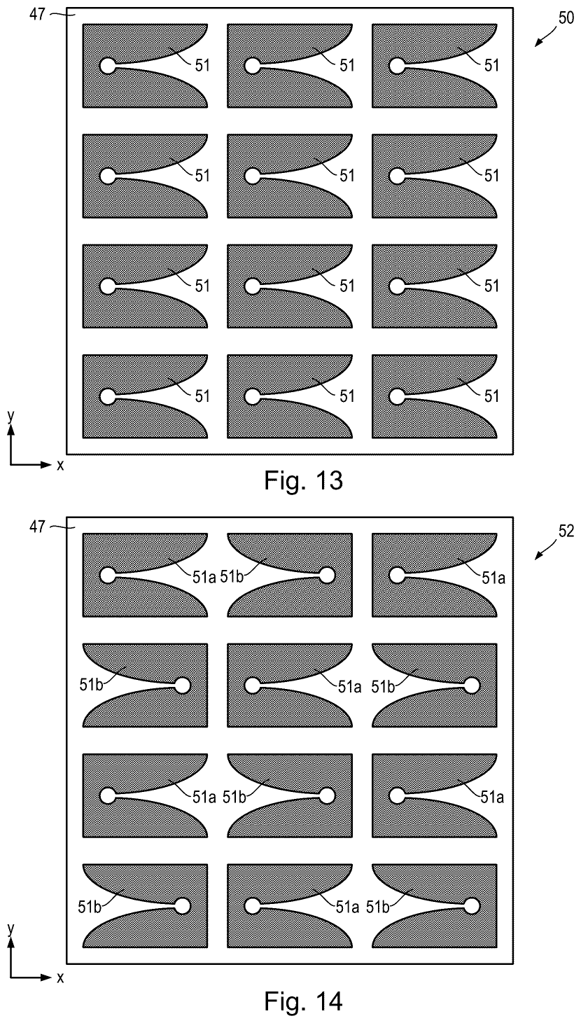

Referring also to FIG. 13, a third exemplary antenna array 50 is shown (hereinafter “third antenna array”).

The third antenna array 50 is a rectangular array of Vivaldi planar antennae 51, each of which may provide an array 16 of antennae 17 for the radio 14. Vivaldi antennae are directional, and each Vivaldi planar antennae 51 emits a radiation pattern with a main lobe centered in a direction parallel to an emission direction (positive x direction using the illustrated axes). The Vivaldi planar antennae 51 are supported on the substrate 47 in the same way as the rectangular and/or ring antennae 46, 49.

Although shown in a rectangular array 50, the Vivaldi planar antennae 51 may be organized according to any (lattice) type or shape of array. Although a four by three array 50 is shown in FIG. 13, an array 50 of the Vivaldi planar antennae 51 may include any numbers M, N of rows and/or columns.

Referring also to FIG. 14, a fourth exemplary antenna array 52 is shown (hereinafter “fourth antenna array”).

When using in-plane directional planar antennae such as the Vivaldi planar antennae 51, they do not all need to be orientated in the same direction. The fourth antenna array 52 differs from the third antenna array 50 in that half the Vivaldi antennae 51a are oriented to emit in one direction (positive x on the axes as illustrated), whilst the remainder 51b are arranged to emit in the opposite direction (negative x on the axes as illustrated). The two orientations are arranged in interpenetrating lattices (rectangular, and centered with a two antenna motif). Motif herein has the meaning known from crystallography and other types of repeating/tessellated patterns, but referring here to an arrangement of antennae relative to a lattice point. The Vivaldi planar antennae 51, are not limited to being parallel/anti-parallel, and a given array may include Vivaldi planar antennae 51 orientated in any direction, arranged according to a lattice with a motif including any number of antennae.

The examples of the first to fourth arrays 45, 48, 50, 52 and respective types of antennae 46, 49, 51 are not-exhaustive, and in general the array 16 of antennae 17 may include any suitable type of planar antenna, or may include combinations of two or more types of planar antenna.

Radio configured to relay or re-broadcast radio signals

Referring again to FIG. 5, the radio 14 may be configured to relay or re-broadcast received radio signals 18.

For example, the radio 14 may use the phase shifter 1 for beamforming to receive radio signals 18 from an incident direction θ₁, or may not actively use the phase shifter 1 and simply receive without beamforming. The latter option may have a lower relative signal strength compared to beamforming to an incident direction θ₁ to a source, but in some cases the incident direction θ₁ may not be known in advance. In response to receiving a radio signal 18, the radio 14 may retransmit/rebroadcast in a transmission direction 62 using the phase shifter 1 for beamforming. A transmission direction 62 may be pre-set or pre-calibrated during installation, or may be included in the radio signals 18 themselves for dynamic configuration. In this way, the radio 14 may time multiplex reception and retransmission using a single array 16 of antennae 17.

In another implementation, a single array 16 of antennae 17 may be divided into two groups (in separate blocks, interpenetrating lattices, etc.). A first group of the antennae 17 may be used for reception whilst a second group (e.g. the complement of the first group) are used for retransmission. The phase shifter 1 configuration is capable of controlling individual phases, and hence can be used to control different blocks/regions, or even interpenetrating arrays, to provide independent operation of such groups of antennae. Such a configuration may enable almost immediate (only signal propagation delays) retransmission of received radio signals 18.

Alternatively, in a further implementation (not shown), the may include a second phase shifter (not shown) which is identical to the (first) phase shifter 1 except that it connects a second array (not shown) of second antennae (not shown) to the radio frequency transceiver circuit 15 (or to a separate, second radio frequency transceiver circuit, not shown). The second array (not shown) of second antennae (not shown) may be configured in any way described for the (first) array 16 of (first) antennae 17. In this way, the (first) phase shifter 1 may be used to control the (first) array 16 as a first phased array, whilst the second phase shifter (not shown) is used to control the second array (not shown) as a second phased array. Such a configuration may enable almost immediate (only signal propagation delays) retransmission of received radio signals 18.

### System of Radios

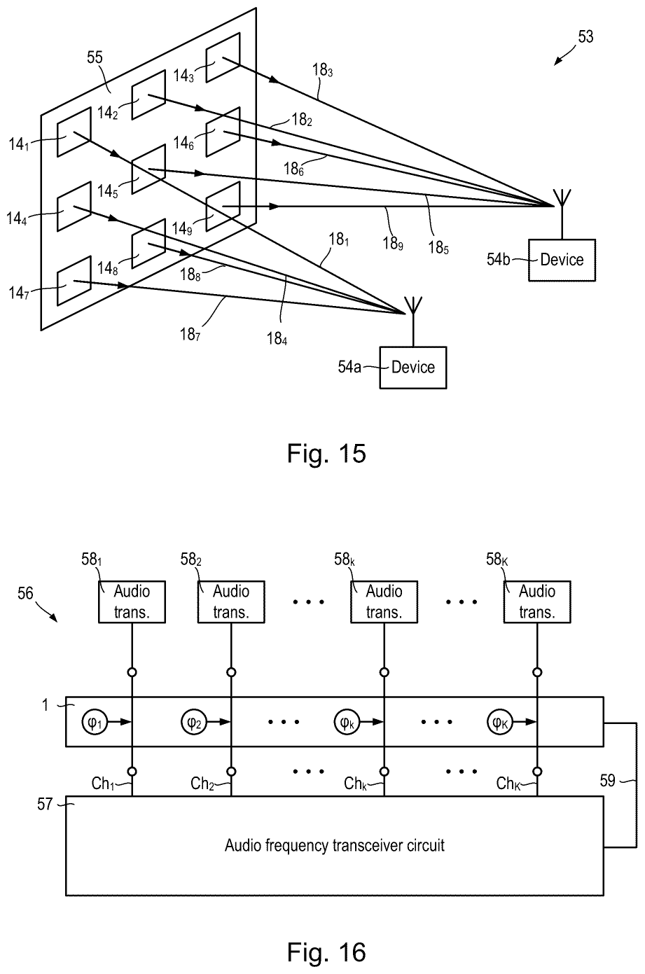

Referring also to FIG. 15, a system 53 is shown which includes a number of radios 14 configured to coordinate with one another.

The system 53 includes a number, as illustrated nine, of radios 14 as described herein. Each radio 14 is configured to coordinate beamforming with each other radio 14 forming part of the system 53. The radios are located in the same general vicinity, for example all within a 200 m sphere, or each within 200 m or less of another radio 14 of the system 53. The coordination of the radios 14 with one another may be achieved by connections via a wired and/or wireless network (not shown). When a wireless network is used, it may operate in the same frequency band as radio signals 18 to be received and/or transmitter, or a different frequency band entirely.

The system 53 may optionally include a central control unit (not shown) configured to coordinate beamforming amongst the radios 14. A central control unit (not shown) may be implemented as a separate, dedicated device, but equally may be provided by one of the radios 14 (e.g. by the controller 6). Alternatively, each radio 14 may include a controller 6 or comparable data processing device, and coordination of beamforming amongst the radios may be executed in a distributed manner, using the controllers 6 of two or more radios 14.

The system 53 is configured to coordinate beamforming of two or more of the radios 14 in order to direct reception and/or transmission of those radios towards a first external source 54a such as a mobile telephone or similar portable device. For example, as illustrated in FIG. 15, radios 141, 144, 147 and 148 may transmit respective radio signals 181, 184, 187, 188 directed towards the first external source 54a. The system 53 may coordinate radios 141, 144, 147 and 148 to control the phases p using respective phase shifters 1 such that signals 181, 184, 187, 188 are not only directed towards to the first external source 54a, but also arrive in phase at the first external source 54a. The latter option requires good synchronization of clocks between the radios 14 of the system, and also calibration of the locations of each radio 14. Precise knowledge of the location of first external source 54a is not necessary, since the path length differences between different radios 14 may be inferred from the implied intersection of beamforming directions θ and calibrated relative locations of the radios 14.

An alternative form of coordination is to determine which radio 14 has the strongest signal for communicating with an external source 54a, and to then use only that radio 14 to transmit signals 18 to that external source 54a. This may help to avoid signal clash between different radios 14 by preventing two or more from trying to communicate with the same external source 54a at the same time.

All of the radios 14 of the system 53 do not need to communicate with the same external source 54a. The system may be configured such that the radios 14 may coordinate beamforming towards at least two spatially separated external sources 54a, 54b. For example, as illustrated in FIG. 15, radios 141, 144, 147 and 148 transmit respective radio signals 181, 184, 187 and 188 directed towards the first external source 54a, whilst the remaining radios 142, 143, 145, 146 and 149 transmit respective radio signals 182, 183, 185, 186 and 189 directed towards the second external source 54b.

The radios 14 forming a system 53 may be supported by a structure 55, for example a building, or a wall, window and so forth of a building. In some examples, the structure 55 may be a bus shelter, a lamp post, or any other item of street furniture. The radios 14 belonging to a system 53 may be supported by two or more separate structures 55 (each structure having any meaning as described hereinbefore).

Although shown arranged in a square/rectangular array in FIG. 15, the radios 14 may be arranged in any other type of array, or need not be arranged in an array at all. Regular arrangement is not required to coordinate phases between radios 14, only knowledge of the relative locations of those radios 14.

### Audio Beamforming

A phase shifter 1 may be configured to apply phase shifts φₖ to audio frequency signals.

Referring also to FIG. 16, an audio device 56 includes a phase shifter 1.

The audio device 56 includes an audio frequency transceiver circuit 57 connected via the phase shifter 1 to a number K of audio transducers 58₁, . . . , 58ₖ, . . . , 58_{K} (e.g. speakers and/or microphones). Each audio transducer 58ₖ is connected to the audio transceiver circuit 57 via a respective signal channel Chₖ of the phase shifter 1.

The phase shifter 1 is configured for audio frequency signals, for example signals having frequencies between and including 20 Hz and 20 kHz. This configuration is primarily provided by the size and range of variable capacitances C(V) as explained hereinbefore. Examples of audio transducers 58 include cone speakers/microphone, piezoelectric speakers/microphones, and so forth.

The audio frequency transceiver circuit 57 is configured to control the audio transducers 58₁, . . . , 58_{K} as a phased array by performing beamforming for reception and/or emission of sound. In this way, the directional audio device 56 may provide a directional microphone and/or directional sound, in an analogous manner to beamforming of radio signals (simply a difference in medium and typical frequencies/wavelengths). For example, the audio frequency transceiver circuit 57 circuit may send control signals 59 to the phase shifter 1. The control signals 59 may take any suitable form in dependence on the configuration of the phase shifter 1, including sending phase images 9 and/or instructions 11. As one example, the instructions 11 may identify a desired beamforming angle θ, and the phase shifter 1 may use a look-up table to retrieve a corresponding phase image 9 (or corresponding voltages V_{n,m} stored in any machine readable format).

The audio device 56 may be configured to support directional audio output and directional microphone input concurrently. For example, some of the audio transducers 58 may provide speakers whilst others 58 provide microphones, with separate beamforming controlled by sub-arrays of the phase shifter 1. Alternatively, the audio device 56 may include a second phase shifter 1 and corresponding second group/set/array of audio transducers 58.

The audio device 56 may include analogous features to any features of the radio 14 described hereinbefore.

### Ultrasonic Beamforming

A phase shifter 1 may be configured to apply phase shifts φₖ to ultrasonic signals.

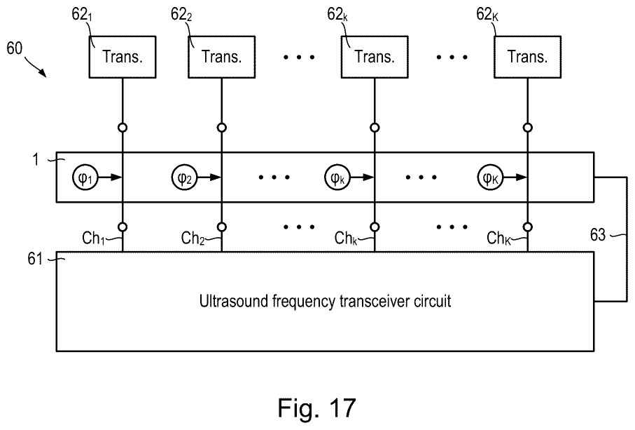

Referring also to FIG. 17, an ultrasonic device 60 includes a phase shifter 1.

The ultrasonic device 60 includes an ultrasonic frequency transceiver circuit 61 connected via the phase shifter 1 to a number K of ultrasonic transducers 62₁, . . . , 62ₖ, . . . , 62_{K} (e.g. ceramic or polymer based piezoelectric transducers). Each ultrasonic transducer 62ₖ is connected to the ultrasonic frequency transceiver circuit 61 via a respective signal channel Chₖ of the phase shifter 1.

The phase shifter 1 is configured for ultrasonic frequency signals, for example signals having frequencies between and including 20 kHz and 18 MHz. This configuration is primarily provided by the size and range of variable capacitances C(V) as explained hereinbefore. Examples of ultrasonic transducers 62 include piezoelectric transducers formed using ceramic or polymeric piezoelectric materials. Ultrasonic transducers 62 may be configured to be directional, and the beamforming provided by the phase shifter 1 may provide further refinement of the innate directionality of such transducers.

The ultrasonic frequency transceiver circuit 61 is configured to control the ultrasonic transducers 62₁, . . . , 62_{K} as a phased array by performing beamforming for reception and/or emission of ultrasonic sound waves. In this way, the ultrasonic device 60 may provide a directional ultrasonic probe, in an analogous manner to beamforming of radio signals (simply a difference in medium and typical frequencies/wavelengths). For example, the ultrasonic frequency transceiver circuit 61 circuit may send control signals 63 to the phase shifter 1. The control signals 63 may take any suitable form in dependence on the configuration of the phase shifter 1, including sending phase images 9 and/or instructions 11. As one example, the instructions 11 may identify a desired beamforming angle θ, and the phase shifter 1 may use a look-up table to retrieve a corresponding phase image 9 (or corresponding voltages V_{n,m} stored in any machine readable format).

The ultrasonic device 60 may be used for a wide range of applications in which ultrasonic sound waves find application, including, but not limited to, non-destructive materials testing (detecting/imaging cracks and so forth), range and/or direction finding, medical scanning/imaging, manipulating and/or modifying materials (for example breakdown of kidney stones) and so forth.

The ultrasonic device 60 may be configured to emit a pulse or burst of ultrasound, and to subsequently switch to a receiving mode to listen for reflected ultrasound. Alternatively, the ultrasonic device 60 may be configured to support directional transmission and reception concurrently. For example, some of the ultrasonic transducers 62 may emit whilst others receive, with separate beamforming controlled by sub-arrays of the phase shifter 1. Alternatively, the ultrasound device 60 may include a second phase shifter 1 and corresponding second group/set/array of ultrasonic transducers 62.

The ultrasonic device 60 may include analogous features to any features of the radio 14 described hereinbefore.

### Modifications

It will be appreciated that many modifications may be made to the embodiments hereinbefore described. Such modifications may involve equivalent and other features which are already known in the design, manufacture and use of phase shifters, radios, audio devices and/or ultrasonic devices, and which may be used instead of or in addition to features already described herein. Features of one embodiment may be replaced or supplemented by features of another embodiment.

Although claims have been formulated in this application to particular combinations of features, it should be understood that the scope of the disclosure of the present disclosure also includes any novel features or any novel combination of features disclosed herein either explicitly or implicitly or any generalization thereof, whether or not it relates to the same invention as presently claimed in any claim and whether or not it mitigates any or all of the same technical problems as does the present disclosure. The applicant hereby gives notice that new claims may be formulated to such features and/or combinations of such features during the prosecution of the present application or of any further application derived therefrom.

1. A phase shifter comprising:
an active matrix transistor array, wherein each transistor of the active matrix transistor array is configured to control a voltage bias across a corresponding voltage-controlled capacitor of voltage-controlled capacitors to control a capacitance of the corresponding voltage-controlled capacitor; and
a plurality of signal channels, wherein each signal channel of the plurality of signal channels has a first end and a second end and is AC coupled at a point between the first end and the second end to one or more of the voltage-controlled capacitors, wherein the phase shifter is configured to control a phase shift applied to each corresponding signal channel of the plurality of signal channels by setting the voltage bias across each of the one or more of the voltage-controlled capacitors coupled to the corresponding signal channel.

2. The phase shifter of claim 1, wherein a storage capacitor is connected in parallel with each of the voltage-controlled capacitors.

3. The phase shifter of claim 1, wherein the active matrix transistor array comprises thin-film transistors.

4. The phase shifter of claim 1, further configured to:
receive or generate a phase image, wherein each pixel of the phase image corresponds to a transistor of the active matrix transistor array and stores a voltage for application to a respective voltage-controlled capacitor of the voltage-controlled capacitors, the respective voltage-controlled capacitor being associated with the transistor; and
set the voltages of each voltage-controlled capacitor of the voltage-controlled capacitors according to the phase image.

5. The phase shifter of claim 1, wherein each respective signal channel of the plurality of signal channels comprises one or more amplifiers between a respective first end and a respective second end of the respective signal channel.

6. The phase shifter of claim 1, wherein each respective signal channel comprises one or more filters between a respective first end and a respective second end of the respective signal channel ends.

7. The phase shifter of claim 2, wherein the active matrix transistor array and the voltage-controlled capacitors are supported by a common substrate.

8. The phase shifter of claim 7, wherein the storage capacitor is supported by the common substrate.

9. The phase shifter of claim 2, wherein the active matrix transistor array and the voltage-controlled capacitors are integrated as a single component.

10. The phase shifter of claim 9, wherein the storage capacitor is integrated with the single component.

11. The phase shifter of claim 9, wherein at least a portion of each signal channel of the plurality of signal channels is integrated with the single component.

12. The phase shifter of claim 1, configured to apply phase shifts to radio frequency signals.

13. A radio comprising:
a first phase shifter comprising:
a first active matrix transistor array, wherein each transistor of the first active matrix transistor array is configured to control a first voltage bias across a first corresponding voltage-controlled capacitor of first voltage-controlled capacitors to control a first capacitance of the first corresponding voltage-controlled capacitor; and
a plurality of first signal channels, wherein each signal channel of the plurality of first signal channels has a first end and a second end and is AC coupled at a point between the first end and the second end to one or more of the first voltage-controlled capacitors, wherein the first phase shifter is configured to control a first phase shift applied to each corresponding first signal channel of the plurality of first signal channels by setting the first voltage bias across each of the one or more of the first voltage-controlled capacitors coupled to the corresponding first signal channel, and wherein the first phase shifter is configured to apply first phase shifts to first radio frequency signals; and
a plurality of first antennae, wherein each first antenna of the plurality of first antennae is connected to a radio frequency transceiver circuit via a respective signal channel of the first phase shifter, wherein the radio frequency transceiver circuit is configured to control the plurality of first antennae as a first phased array by performing beamforming of radio signals at least one of received by or transmitted from the plurality of first antennae using the first phase shifter.

14. The radio of claim 13, wherein each first antenna of the plurality of first antennae is connected to the respective signal channel of the first phase shifter via one or more amplifiers.

15. The radio of claim 13, wherein each first antenna of the plurality of first antennae is connected to the respective signal channel of the first phase shifter via one or more filters.

16. The radio of claim 13, wherein the plurality of first antennae are disposed in an array.

17. The radio of claim 13, wherein the plurality of first antennae are integrated with the first phase shifter on a same substrate or within a same laminate.

18. The radio of claim 13, wherein the plurality of first antennae are supported on a transparent substrate.

19. The radio of claim 13, therein the radio is configured to relay or re-broadcast received radio signals.

20. The radio of claim 13, further comprising:
a second phase shifter comprising:
a second active matrix transistor array, wherein each transistor of the second active matrix transistor array is configured to control a second voltage bias across a second corresponding voltage-controlled capacitor of second voltage-controlled capacitors to control a second capacitance of the second corresponding voltage-controlled capacitor; and
a plurality of second signal channels, wherein each signal channel of the plurality of second signal channels has a corresponding first end and a corresponding second end and is AC coupled at a corresponding point between the corresponding first end and the corresponding second end to one or more of the second voltage-controlled capacitors, wherein the second phase shifter is configured to control a second phase shift applied to each corresponding second signal channel of the plurality of second signal channels by setting the second voltage bias across each of the one or more of the second voltage-controlled capacitors coupled to the corresponding second signal channel, and wherein the second phase shifter is configured to apply second phase shifts to second radio frequency signals; and
a plurality of second antennae, wherein each second antenna of the plurality of second antennae is connected to the radio frequency transceiver circuit via a corresponding signal channel of the second phase shifter, wherein the radio frequency transceiver circuit is configured to:
control, using the first phase shifter, the plurality of first antennae as the first phased array to receive the radio signals, the first phased array being directional and controllably orientable to a receive direction; and
control, using the second phase shifter, the plurality of second antennae as a second phased array to retransmit the radio signals received using the first phased array, the second phased array being directional and controllably orientable to a transmit direction.

21. A system comprising a plurality of radios, wherein each radio of the plurality of radios comprises:
a phase shifter comprising:
an active matrix transistor array, wherein each transistor of the active matrix transistor array is configured to control a voltage bias across a corresponding voltage-controlled capacitor of voltage-controlled capacitors to control a capacitance of the corresponding voltage-controlled capacitor; and
a plurality of signal channels, wherein each signal channel of the plurality of signal channels has a first end and a second end and is AC coupled at a point between the first end and the second end to one or more of the voltage-controlled capacitors, wherein the phase shifter is configured to control a phase shift applied to each corresponding signal channel of the plurality of signal channels by setting the voltage bias across each of the one or more of the voltage-controlled capacitors coupled to the corresponding signal channel, and wherein the phase shifter is configured to apply phase shifts to radio frequency signals; and
a plurality of antennae, wherein each antenna of the plurality of antennae is connected to a radio frequency transceiver circuit via a respective signal channel of the phase shifter, wherein the radio frequency transceiver circuit is configured to control the plurality of antennae as a first phased array by performing beamforming of radio signals at least one of received by or transmitted from the plurality of antennae using the phase shifter, wherein each radio of the plurality of radios is configured to coordinate beamforming with each other radio of the plurality of radios.

22. The system of claim 21, wherein the plurality of radios are configured to coordinate beamforming to direct one or more of reception or transmission of two or more of the plurality of radios towards a first external source.

23. The system of claim 21, wherein the plurality of radios are configured to coordinate beamforming towards at least two spatially separated external sources.

24. The system of claim 21, wherein the plurality of radios are supported by a structure.

25. A method of controlling a phase shifter, the method comprising:
addressing each transistor of an active matrix transistor array of the phase shifter; and
setting voltage across a corresponding voltage-controlled capacitor of the voltage-controlled capacitors of the phase shifter to cause a capacitance of the corresponding voltage-controlled capacitor to correspond to a given phase shift of a signal propagating via a signal channel of a plurality of signal channels of the phase shifter, wherein each signal channel of the plurality of signal channels has a first end and a second end and is AC coupled at a point between the first end and the second end to one or more of the voltage-controlled capacitors, wherein the phase shifter is configured to control a phase shift applied to each corresponding signal channel of the plurality of signal channels by the setting of the voltage across each of the one or more of the voltage-controlled capacitors coupled to the corresponding signal channel.
